(19) United States
(12) Patent Application Publication
(10) Pub. No.: US 2016/0118621 A1
(43) Pub. Date: Apr. 28, 2016

(54) HYBRID BARRIER LAYER FOR SUBSTRATES AND ELECTRONIC DEVICES

(71) Applicant: UNIVERSAL DISPLAY CORPORATION, Ewing, NJ (US)

(72) Inventors: Siddharth HARIKRISHNA MOHAN, Plainsboro, NJ (US); William E. QUINN, Whitehouse Station, NJ (US); Ruiqing MA, Morristown, NJ (US)

(21) Appl. No.: 14/893,436

(22) PCT Filed: Jun. 21, 2014
(86) PCT No.: PCT/US14/43538

§ 371 Date: Nov. 23, 2015

Related U.S. Application Data
(60) Provisional application No. 61/837,689, filed on Jun. 21, 2013.

(51) Int. Cl. H01L 51/52

(52) U.S. Cl. CPC H01L 51/5253; H01L 2251/5338

(57) ABSTRACT

Systems and techniques for depositing multiple different organic precursors, with reactive gases, such as by plasma polymerization, are provided. Using multiple precursor materials may provide for a much larger process regime, thus enabling for precise tuning of barrier properties and stress of the films. A barrier film as disclosed herein may be used on variety of substrates and electronic devices to reduce the permeation of moisture and other atmospheric contaminants.

### PRIORITY

This application claims priority to U.S. Provisional Application No. 61/837,689, filed Jun. 21, 2013, the disclosure of which is incorporated by reference in its entirety.

The claimed invention was made by, on behalf of and/or in connection with one or more of the following parties to a joint university corporation research agreement: Regents of the University of Michigan, Princeton University, The University of Southern California, and the Universal Display Corporation. The agreement was in effect on and before the date the claimed invention was made, and the claimed invention was made as a result of activities undertaken within the scope of the agreement.

### FIELD OF THE INVENTION

The present invention relates to organic light emitting devices (OLEDs) and, more specifically, to hybrid barriers suitable for use with OLEDs and techniques for fabricating the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art.

One example of a green emissive molecule is tris(2-phenylpyridine) iridium, denoted Ir(ppy)₃, which has the following structure:

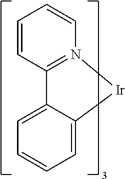

In this, and later figures herein, we depict the dative bond from nitrogen to metal (here, Ir) as a straight line.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

### SUMMARY OF THE INVENTION

In an aspect of the invention, multiple precursor materials may be provided at a reaction location adjacent to a surface, at least one of which includes an organosilicon material. The multiple precursor materials may be reacted, such as by chemical vapor deposition or plasma polymerization, to form a hybrid layer, such as a flexible barrier film, from the plurality of precursor materials on the surface. The plurality of precursor materials may include two monomer materials having different disassociation rates. The precursor materials may be transported to the reaction location by a carrier gas. The precursor materials may be selected based upon desired attributes of the hybrid film.

In an aspect of the invention, a value for a parameter of a hybrid film may be selected, such as deposition pressure at the reaction location; total flow rate of the plurality of precursor materials to the reaction location; relative ratio of a first of the plurality of precursor materials at the reaction location to a second of the precursor materials; and deposition power. Multiple precursor material may then be reacted at the selected parameter value. Selection of the process parameter may be made based upon a desired attribute of the deposited hybrid film. Each of the precursor materials may include a mixture of hexamethyl disiloxane and tetrathylorthosilicate; methylsilane; dimethylsilane; vinyl trimethylsilane; trimethylsilane; tetramethylsilane; ethylsilane; disilanomethane; bis(methylsilano)methane; 1,2-disilanoethane; 1,2-bis(methylsilano)ethane; 2,2-disilanopropane; 1,3,5-trisilano-2,4,6-trimethylene; dimethylphenylsilane; diphenylmethylsilane; tetraethylortho silicate; dimethyldimethoxysilane; 1,3,5,7-tetramethylcyclotetrasiloxane; 1,3-dimethyldisiloxane; 1,1,3,3-tetramethyldisiloxane; 1,3-bis(silanomethylene)disiloxane; bis(1-methyldisiloxanyl)methane; 2,2-bis(1-methyldisiloxanyl)propane; 2,4,6,8-tetramethylcyclotetrasiloxane; octamethylcyclotetrasiloxane; 2,4,6,8,10-pentamethylcyclopentasiloxane; 1,3,5,7-tetrasilano-2,6-dioxy-4,8-dimethylene; hexamethylcyclotrisiloxane; 1,3,5,7,9-pentamethylcyclopentasiloxane; hexamethoxydisiloxane; hexamethyldisilazane; divinyltetramethyldisilizane; hexamethylcyclotrisilazane; dimethylbis(Nmethylacetamido)silane; dimethylbis-(N-ethylacetamido)silane; methylvinylbis(Nmethylacetamido)silane; methylvinylbis(N-butylacetamido)silane; methyltris(Nphenylacetamido)silane; vinyltris(N-ethylacetamido)silane; tetrakis(N-methylacetamido)silane; diphenylbis(diethylaminoxy)silane; methyltris(diethylaminoxy)silane; and bis(trimethylsilyl)carbodiimide. A thickness of 1 micron of the hybrid film may have a permeation of not more than 10-1 g/m2/day at 38 deg, 90 pct humidity.

In an aspect of the invention, a device includes a hybrid film fabricated as previously described. The device may be, for example, an OLED a flat panel display, a computer monitor, a medical monitor, a television, a billboard, a light for interior or exterior illumination and/or signaling, a heads-up display, a fully transparent display, a flexible display, a laser printer, a telephone, a cell phone, a smartphone, a personal digital assistant (PDA), a laptop computer, a digital camera, a camcorder, a viewfinder, a micro-display, a 3-D display, a vehicle, a large area wall, theater or stadium screen, or a sign.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows the vapor pressure vs. temperature of HMDSO and TEOS.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

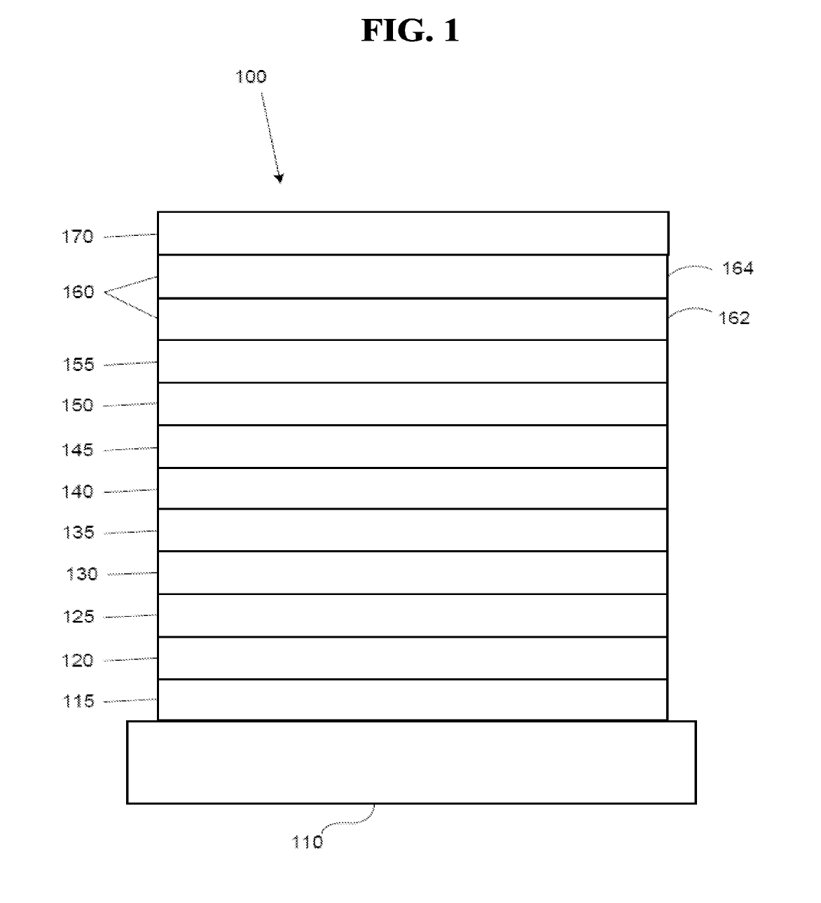

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F4-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

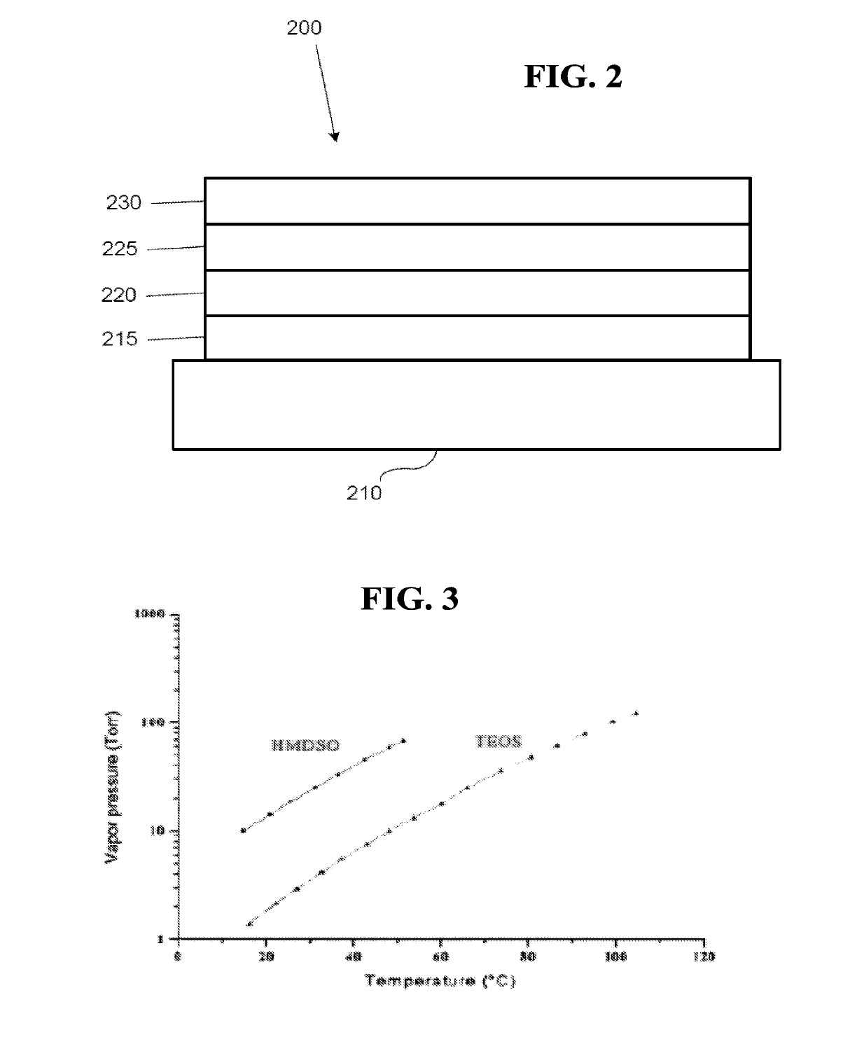

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink jet and OVJP. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention may be incorporated into a wide variety of consumer products, including flat panel displays, computer monitors, medical monitors, televisions, billboards, lights for interior or exterior illumination and/or signaling, heads up displays, fully transparent displays, flexible displays, laser printers, telephones, cell phones, personal digital assistants (PDAs), laptop computers, digital cameras, camcorders, viewfinders, micro-displays, 3-D displays, vehicles, a large area wall, theater or stadium screen, or a sign. Various control mechanisms may be used to control devices fabricated in accordance with the present invention, including passive matrix and active matrix. Many of the devices are intended for use in a temperature range comfortable to humans, such as 18 degrees C. to 30 degrees C., and more preferably at room temperature (20-25 degrees C.), but could be used outside this temperature range, for example, from −40 degree C. to +80 degree C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

Organic electronic devices, such as OLEDs, often are vulnerable to degradation when exposed to water vapor or oxygen. A protective barrier coating over the OLED to reduce its exposure to water vapor or oxygen may improve the lifetime and performance of the device. Films of silicon oxide, silicon nitride, or aluminum oxide, which have been successfully used in food packaging, have been considered for use as barrier coatings for OLEDs. However, these inorganic films tend to contain microscopic defects which allow some diffusion of water vapor and oxygen through the film. In some cases, the defects open as cracks in the brittle film. While this level of water and oxygen diffusion may be acceptable for food products, it is not acceptable for OLEDs. To address these problems, multilayer barrier coatings that use alternating inorganic and polymer layers have been tested on OLEDs and found to have improved resistance to water vapor and oxygen penetration. However, such multilayer coatings typically have the disadvantages of high complexity and cost. Organic electronic devices such as OLEDs also may be fabricated on many types of substrates such as glass, amorphous silicon, metal foil, and flexible polymeric substrates such as poly ethylene terephthalate (PET), poly ethylene naphthalate (PEN), etc. However, polymeric substrates made with these materials typically do not provide adequate barrier properties to protect the OLED from moisture or oxygen. Thus, there is a need for other methods of forming barrier coatings suitable for use in protecting OLEDs. One such barrier coating process is described in U.S. Pat. No. 7,968,146, and International Application Nos. PCT/US2007/023098 and PCT/US2009/042829. The barrier film described was grown by plasma polymerization of HMDSO with a reactive gas such as oxygen. This barrier has an organic-inorganic hybrid nature. In PECVD of HMDSO/O₂, the monomer molecules are activated by collision with electrons and possibly with O atoms or with excited O₂ molecules. This activation is believed to cause dissociative ionization, which removes a CH₃ group from the monomer. Because the bond energy of Si—O bond in the HMDSO molecule is 8.3 eV, which is more than the bond energy of Si—C bond (4.6 eV) and the C—H bond (3.5 eV), the Si—C and C—H bonds are broken upon electron collision. The activated fragments can react with O₂ to form fully or partially oxidized hydrocarbons and low molecular-weight siloxy compounds. The extent of polymerization reactions taking place in the gas phase can be controlled by deposition pressure, HMDSO/O₂ gas flow ratio, and deposition power. These parameters can be tuned to form a hybrid film anywhere between SiOxCyHz (silicone-like) films and SiO₂-like/non-polymeric films. In certain types of equipment configurations, the SiO₂ like films may have high stress but very good barrier properties while the silicone like films tend to have lower stress and are generally poor barriers. Although a flexible hybrid barrier layer is realizable, there typically exists a trade-off between the permeation barrier property and stress of the films in the above method. A better deposition method with a wide process regime to obtain a hybrid flexible barrier film is needed.

As described herein, multiple different organic precursors, with reactive gases, may be plasma polymerized to deposit a hybrid barrier layer, eg: HMDSO/O₂+TEOS/O₂. Using multiple precursor materials may provide for a much larger process regime, thus enabling for precise tuning of barrier properties and stress of the films. A barrier film as disclosed herein may be used on variety of substrates and electronic devices to reduce the permeation of moisture and other atmospheric contaminants.

In an embodiment of the invention, multiple precursor materials may be provided at a reaction location, for example, adjacent to a substrate surface on which a barrier layer is to be deposited. The precursors may be provided using any known technique. For example, each precursor may be transported to the reaction location using one or more carrier gases. In some configurations, one or more precursors may be introduced to the reaction location, after which one or more other precursors may be transported via carrier gas. It may be preferred for at least one of the precursor materials to include an organosilicon material. Once provided at the reaction location, the precursors may be reacted, such as by chemical vapor deposition, plasma polymerization, or the like, to form a hybrid layer from the precursor materials on the surface. It may be preferred for the different precursors to be selected such that they include structures or materials, such as monomer materials, that have different disassociation rates. This may allow for finer control over the combined reaction used to form the hybrid layer on the surface.

As an example, one such technique is to plasma polymerize multiple organic precursor materials to obtain a flexible hybrid barrier film. At a fixed process condition, different monomers will have different disassociation rates due to inherent variance in bond energies. For example, to obtain a hybrid barrier SiO₂ like film, plasma polymerization of two organosilicon precursors such as HMDSO and teteraethylorthosilicate (TEOS) with a reactive gas such as O₂ can be performed simultaneously in a single vacuum chamber. Carrier gases such as Ar, N₂, N₂O, He etc. may further be introduced into the process. FIG. 3 shows the vapor pressure vs. temperature of HMDSO and TEOS. As illustrated, HMDSO is a more volatile precursor than TEOS, which suggests a heating unit will be necessary to introduce TEOS. Since TEOS possesses a tetraedric silicon environment that is similar to that met in SiO₂, it is expected to give SiO₂ films and hence typically a good barrier property if the core structure of TEOS is preserved. Further, the bond energy of Si—O bond in the TEOS molecule is 8.3 eV, which is more than the bond energy of a C—C bond (3.6 eV), C—H bond (4.3 eV) and C—O bond (3.7 eV), the C—C, C—H, and C—O bonds are easily broken upon electron collision. Additionally in independent studies performed by Raynaud et al. and Ito et al., it has been observed that the disassociation of TEOS is relatively easier than the disassociation of HMDSO.

Thus, according to an example embodiment of the current invention, if HMDSO and TEOS are plasma polymerized simultaneously with O₂ carrier gas, there exists a process regime where the TEOS molecules can undergo complete disassociation while the HMDSO molecules undergo partial disassociation. It is therefore possible to obtain a hybrid barrier film in which polymerized TEOS primarily accounts for the SiO₂-like nature of the film, while the partially-polymerized HMDSO incorporates C and H groups in the film and thereby reduces stress. The barrier properties and stress of the resultant hybrid SiOxCyHz film can be tuned by controlling the extent of polymerization of the individual precursors. Process parameters such as deposition pressure, total flow/feed rate, organosilicon/O₂ gas flow ratio, ratio of organosilicon precursors, partial pressure of precursors and deposition power can be varied to obtain the desired flexible hybrid barrier film. For example, a hybrid film may be deposited that has a permeation at 1 micron thickness of not more than 0.1 g/m²/day at 38 C and 90% humidity. In general, it is possible to “trade” one property for another by selecting appropriate precursors and/or the relative ratios of the precursors. For example, by using one precursor material that provides good barrier properties but relatively poor flexibility, and another that improves flexibility but has relatively poor barrier properties, the resulting hybrid film may have a flexibility better than if the first precursor was used alone, and barrier properties better than if the second precursor was used alone. More generally, multiple properties of the resulting hybrid barrier film may be adjusted by selection of the appropriate precursors and relative ratios.

A wide range of organosilicon precursors can be used in embodiments of the invention. Organo-silicon compounds suitable for use as a precursor material include methylsilane; dimethylsilane; vinyl trimethylsilane; trimethylsilane; tetramethylsilane; ethylsilane; disilanomethane; bis(methylsilano)methane; 1,2-disilanoethane; 1,2-bis(methylsilano)ethane; 2,2-disilanopropane; 1,3,5-trisilano-2,4,6-trimethylene, and fluorinated derivatives of these compounds.

Phenyl containing organo-silicon compounds suitable for use as a precursor material include: dimethylphenylsilane and diphenylmethylsilane.

Oxygen-containing organo-silicon compounds suitable for use as a precursor material include: tetraethylortho silicate; dimethyldimethoxysilane; 1,3,5,7-tetramethylcyclotetrasiloxane; 1,3-dimethyldisiloxane; 1,1,3,3-tetramethyldisiloxane; 1,3-bis(silanomethylene)disiloxane; bis(1-methyldisiloxanyl)methane; 2,2-bis (1-methyldisiloxanyl)propane; 2,4,6,8-tetramethylcyclotetrasiloxane; octamethylcyclotetrasiloxane; 2,4,6,8,10-pentamethylcyclopentasiloxane; 1,3,5,7-tetrasilano-2,6-dioxy-4,8-dimethylene; hexamethylcyclotrisiloxane; 1,3,5,7,9-pentamethylcyclopentasiloxane; hexamethoxydisiloxane, and fluorinated derivatives of these compounds.

Nitrogen-containing organo-silicon compounds suitable for use as a precursor material include: hexamethyldisilazane; divinyltetramethyldisilizane; hexamethylcyclotrisilazane; dimethylbis(Nmethylacetamido)silane; dimethylbis-(N-ethylacetamido)silane; methylvinylbis(Nmethylacetamido)silane; methylvinylbis(N-butylacetamido)silane; methyltris(Nphenylacetamido)silane; vinyltris(N-ethylacetamido)silane; tetrakis(N-methylacetamido)silane; diphenylbis(diethylaminoxy)silane; methyltris(diethylaminoxy)silane; and bis(trimethylsilyl)carbodiimide.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A method comprising:
providing a plurality of precursor materials at a reaction location adjacent to a surface, at least one of the plurality of precursor materials comprising an organosilicon material; and
reacting the plurality of precursor materials at the reaction location to form a hybrid layer from the plurality of precursor materials on the surface.

2. The method of claim 1, wherein reacting the plurality of precursor materials comprises performing a chemical vapor deposition process to react the plurality of precursor materials.

3. The method of claim 1, wherein reacting the plurality of precursor materials comprises plasma polymerizing each of the plurality of precursor materials at the reaction location.

4. The method of claim 1, wherein the plurality of precursor materials comprise two monomer materials having different disassociation rates.

5. The method of claim 1, wherein the hybrid layer is a flexible barrier film.

6. The method of claim 1, wherein providing the plurality of precursor materials at the reaction location comprises transporting at least one of the plurality of precursor materials to the reaction location by a carrier gas.

7. The method of claim 1, further comprising:
selecting a value for a parameter selected from the group consisting of: deposition pressure at the reaction location; total flow rate of the plurality of precursor materials to the reaction location; relative ratio of a first of the plurality of precursor materials at the reaction location to a second of the precursor materials; and deposition power; and
reacting the plurality of precursor materials at the selected parameter value.

8. The method of claim 7, wherein the parameter value is selected based upon a desired attribute of the deposited hybrid film.

9. The method of claim 1, wherein each of the plurality of precursor materials is selected based upon a desired property of the hybrid film.

10. The method of claim 1, wherein at least one of the plurality of precursor materials comprises a mixture of hexamethyl disiloxane and tetrathylorthosilicate.

11. The method of claim 1, wherein each of the plurality of precursor materials is independently selected from the group consisting of: methylsilane; dimethylsilane; vinyl trimethylsilane; trimethylsilane; tetramethylsilane; ethylsilane; disilanomethane; bis(methylsilano)methane; 1,2-disilanoethane; 1,2-bis(methylsilano)ethane; 2,2-disilanopropane; 1,3,5-trisilano-2,4,6-trimethylene; dimethylphenylsilane; diphenylmethylsilane; tetraethylortho silicate; dimethyldimethoxysilane; 1,3,5,7-tetramethylcyclotetrasiloxane; 1,3-dimethyldisiloxane; 1,1,3,3-tetramethyldisiloxane; 1,3-bis(silanomethylene)disiloxane; bis(1-methyldisiloxanyl)methane; 2,2-bis(1-methyldisiloxanyl)propane; 2,4,6,8-tetramethylcyclotetrasiloxane; octamethylcyclotetrasiloxane; 2,4,6,8,10-pentamethylcyclopentasiloxane; 1,3,5,7-tetrasilano-2,6-dioxy-4,8-dimethylene; hexamethylcyclotrisiloxane; 1,3,5,7,9-pentamethylcyclopentasiloxane; hexamethoxydisiloxane; hexamethyldisilazane; divinyltetramethyldisilizane; hexamethylcyclotrisilazane; dimethylbis(Nmethylacetamido)silane; dimethylbis-(N-ethylacetamido)silane; methylvinylbis(Nmethylacetamido)silane; methylvinylbis(N-butylacetamido)silane; methyltris(Nphenylacetamido)silane; vinyltris(N-ethylacetamido)silane; tetrakis(N-methylacetamido)silane; diphenylbis(diethylaminoxy)silane; methyltris(diethylaminoxy)silane; and bis(trimethylsilyl)carbodiimide.

12. The method of claim 1, wherein a thickness of 1 micron of the hybrid film has a permeation of not more than 10-1 g/m2/day at 38 deg, 90 pct humidity.

13. A device fabricated according to the method of claim 1.

14. The device of claim 13, wherein the device comprises an OLED.

15. The method of claim 13, wherein the device comprises a flat panel display, a computer monitor, a medical monitor, a television, a billboard, a light for interior or exterior illumination and/or signaling, a heads-up display, a fully transparent display, a flexible display, a laser printer, a telephone, a cell phone, a smartphone, a personal digital assistant (PDA), a laptop computer, a digital camera, a camcorder, a viewfinder, a micro-display, a 3-D display, a vehicle, a large area wall, theater or stadium screen, or a sign.
